(19) United States
(12) Patent Application Publication
(10) Pub. No.: US 2008/0238513 A1
(43) Pub. Date: Oct. 2, 2008

(54) Hysteresis Circuit Without Static Quiescent Current

(75) Inventors: Ilie Marian I. Poenaru, Bucharest (RO); Alina I. Negut, Bucharest (RO); Sorin S. Georgescu, San Jose, CA (US)

Correspondence Address: BEVER HOFFMAN & HARMS, LLP;2099 Gateway Place, Suite 320, San Jose, CA, 95110, US

(73) Assignee: Catalyst Semiconductor, Inc., Santa Clara, CA (US)

(21) Appl. No.: 11/693,657

(22) Filed: Mar. 29, 2007

(51) Int. Cl. H03K 3/00

(52) U.S. Cl. 327/205

(57) ABSTRACT

A hysteresis circuit including a comparator and capacitive voltage divider circuit. The capacitive voltage divider circuit includes a first capacitor coupled between an input terminal and a positive comparator input, a second capacitor coupled between ground and the positive comparator input, and a third capacitor coupled between the comparator output and positive comparator input. A reference voltage is applied to the negative comparator input. The comparator is powered by the input signal provided on the input terminal. When the voltage on the positive comparator input is less than the reference voltage, the third capacitor is effectively coupled in parallel with the first capacitor. When the voltage on the positive comparator input is greater than the reference voltage, the third capacitor is effectively coupled in parallel with the second capacitor.

### BACKGROUND OF THE INVENTION

1. Field of the Invention

The present invention is in the field of integrated circuits using standard CMOS technology.

2. Related Art

FIG. 1 is a circuit diagram of a conventional Schmitt trigger circuit 100, which includes comparator 101 and resistors 102-105. An input signal S_{IN} is applied to the negative input terminal of comparator 101. The positive input terminal of comparator 101 is coupled to a V_{DD} voltage supply terminal through resistor 102. The positive input terminal of comparator 101 is also coupled to a ground terminal through resistor 103. The voltage on the positive input terminal of comparator 101 is designated as the voltage V_{P}.

The output terminal of comparator 101 is coupled to the V_{DD} voltage supply terminal through resistor 105. The output terminal of comparator 101 is also coupled to the positive input terminal of comparator 101 through feedback resistor 104. Feedback resistor 104 introduces hysteresis to the output signal S_{OUT} provided on the output terminal of Schmitt trigger circuit 100. The hysteresis characteristic of the output signal S_{OUT} is useful in many conventional circuits.

Most popular hysteresis circuits use a feedback resistor coupled between the output of a comparator and an input of the comparator, similar to feedback resistor 104 of Schmitt trigger circuit 100.

Another popular technique to generate hysteresis is to switch a current branch coupled to an output of the comparator, such that this current branch is coupled in parallel with one branch of a differential pair present within the comparator. FIG. 2 is a circuit diagram of a comparator 200, which implements such a technique. Comparator 200 includes differential input stage 10, which includes differential pair transistors 22 and 24, differential pair current mirror transistors 26 and 28, and a constant current source transistor 30. The comparator 200 also includes a hysteresis stage 12 coupled in parallel with one of the current mirror transistors (i.e., current mirror transistor 28). Hysteresis stage 12 includes a hysteresis mirror transistor 34 and a switching transistor 36. Comparator 200 also includes a gain stage 14 comprising a gain transistor 38 and a constant current source transistor 40. Finally, comparator 200 includes an output stage 15 comprising gain transistor 42 in an open drain configuration, and a reference voltage source 32.

When the potential of the gate electrode of switching transistor 36 is sufficient to turn on this transistor, hysteresis stage 12 provides a parallel path to current mirror transistor 28, thereby creating a current sharing configuration. When the potential of the gate electrode of switching transistor 36 causes this transistor to turn off, hysteresis stage 12 draws no current from current mirror transistor 28. In this manner, switching transistor 36 causes hysteresis stage 12 to be selectively switched in and out as a parallel in current path to current mirror transistor 28, thereby introducing hysteresis to comparator 200. Comparator 200 is described in more detail in U.S. Pat. No. 5,808,496 to Thiel.

The above-described hysteresis implementations increase the quiescent current of the associated circuits. The techniques used to reduce this high quiescent current result in spreading the hysteresis voltage, because of mismatching that exists in the current mirrors and/or resistors.

It would therefore be desirable to have an improved hysteresis circuit, which simplifies the design and control of the hysteresis. It would further be desirable if such circuit exhibited fast operation and a low quiescent current. It would further be desirable if such circuit had a small layout area.

### SUMMARY

Accordingly, the present invention provides a hysteresis circuit that includes a comparator that operates in response to a capacitive voltage divider circuit. The capacitive voltage divider circuit includes a first capacitor coupled between an input terminal of the hysteresis circuit and the positive input terminal of the comparator. The input terminal is configured to receive an input signal having a voltage swing that is less than the V_{DD} supply voltage of the circuit. The capacitive voltage divider circuit also includes a second capacitor coupled between a ground supply terminal and the positive input terminal of the comparator. The capacitive voltage divider circuit also includes a third capacitor coupled between the output terminal of the comparator and the positive input terminal of the capacitor.

In one embodiment, the comparator is powered by the input signal and the ground supply voltage, such that the output of the comparator swings between the input voltage and ground. In another embodiment, the comparator is powered by the V_{DD} supply voltage and ground, and a level shifter is included between the output of the comparator and third capacitor.

A reference voltage is applied to the negative input terminal of the comparator. When the voltage on the positive input terminal of the comparator is less than the reference voltage, the third capacitor is effectively coupled in parallel with the first capacitor. When the voltage on the positive input terminal of the comparator is greater than the reference voltage, the third capacitor is effectively coupled in parallel with the second capacitor. This configuration provides a hysteresis voltage that can be readily selected by selecting the capacitances of the first, second and third capacitors. The hysteresis circuit of the present invention advantageously requires a relatively small layout area, because no resistors are used. The use of the capacitive voltage divider circuit also advantageously eliminates quiescent current within the hysteresis circuit.

The present invention will be more fully understood in view of the following description and drawings.

### BRIEF DESCRIPTION OF THE DRAWINGS

FIG. 1 is a circuit diagram of a conventional Schmitt trigger circuit.

FIG. 2 is a circuit diagram of a conventional circuit that generates hysteresis by switching a current branch coupled to an output of a comparator.

FIG. 3 is a circuit diagram of a hysteresis circuit in accordance with one embodiment of the present invention.

FIGS. 4A and 4B are circuit diagrams illustrating voltage divider circuits formed by capacitors present in the hysteresis circuit of FIG. 3, when an input voltage of the hysteresis circuit is less than a reference voltage.

FIGS. 5A and 5B are circuit diagrams illustrating voltage divider circuits formed by capacitors present in the hysteresis circuit of FIG. 3, when an input voltage of the hysteresis circuit is greater than a reference voltage.

FIG. 6 is a circuit diagram of a comparator formed by inserting a level shifter circuit into the hysteresis circuit of FIG. 3.

### DETAILED DESCRIPTION

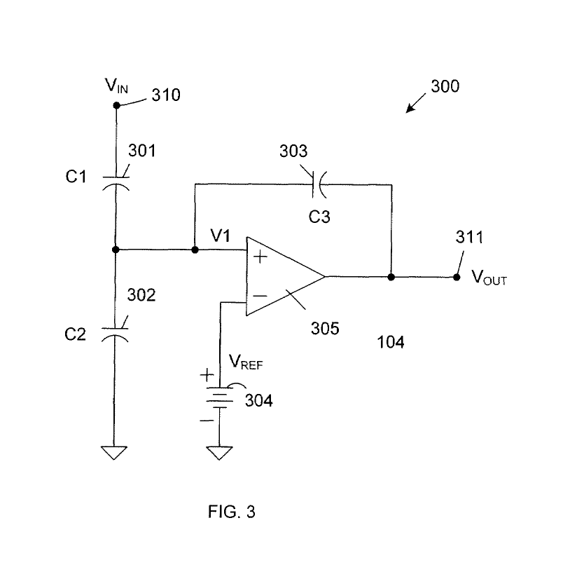

FIG. 3 is a circuit diagram of a hysteresis circuit 300 in accordance with one embodiment of the present invention. Hysteresis circuit 300 includes capacitors 301-303, reference voltage circuit 304 and comparator 305. As described in more detail below, hysteresis circuit 300 generates an output signal V_{OUT} having hysteresis. The hysteresis circuit 300 provides the output signal V_{OUT} on output terminal 311 in response to an input signal V_{IN} provided on input terminal 310. Comparator 305 is supplied by the V_{IN} signal provided on input terminal 310, while the reference voltage circuit 304 may operate in response to a different supply, such as a V_{DD} voltage supply.

The hysteresis circuit 300 uses a capacitive voltage divider, which includes main capacitors 301 and 302 and feedback capacitor 303, to apply a voltage (V1) to the positive input terminal of comparator 305. Capacitors 301, 302 and 303 have capacitances C1, C2 and C3, respectively. Main capacitor 301 is coupled between the positive input terminal of comparator 305 and the input terminal 310. Main capacitor 302 is coupled between the positive input terminal of comparator 305 and the ground terminal. Feedback capacitor 303 is coupled between the output terminal of comparator 305 and the positive input terminal of comparator 305. The output terminal of comparator 305 (and thereby, the counter-electrode of feedback capacitor 303) switches between V_{IN} and ground. Because there is no current flow through a capacitor when biased by a direct current, feedback capacitor 303 reduces the quiescent current of hysteresis circuit 300 to zero in static mode (i.e., direct current mode).

The negative input terminal of comparator 305 is coupled to receive a reference voltage V_{REF} from reference voltage source 304. In one embodiment, reference voltage source 304 may be implemented by circuitry described in commonly owned U.S. patent application Ser. No. 11/611,665 (filed on Dec. 15, 2006), which is hereby incorporated by reference in its entirety.

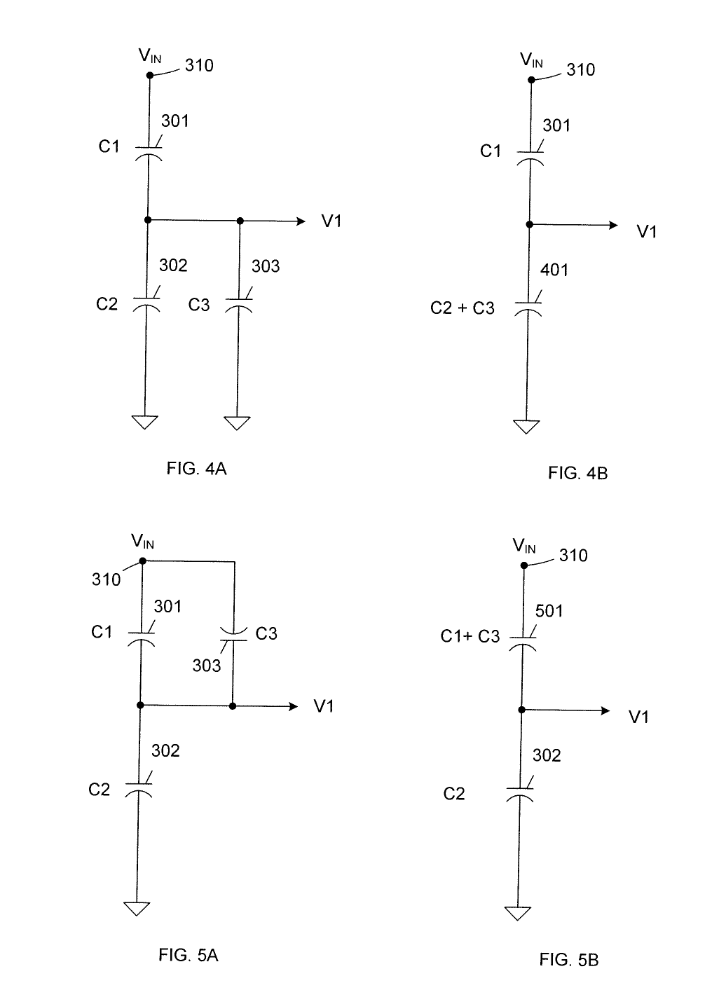

Hysteresis circuit 300 operates as follows. When the voltage V1 applied to the positive input terminal of comparator 305 is less than the reference voltage V_{REF} applied to the negative input terminal of comparator 305, the output voltage V_{OUT} provided by hysteresis circuit 300 is 0 Volts (ground). Under these conditions, the voltage divider circuit including capacitors 301-303 may be drawn as illustrated in FIG. 4A (wherein the counter-electrode of capacitor 303 is coupled to ground). Because the total capacitance of parallel-connected capacitors is equal to the sum of their capacitances, the voltage divider circuit of FIG. 4A may be re-drawn as illustrated in FIG. 4B. Note that capacitors 302 and 303 are replaced with an equivalent capacitor 401 (having a capacitance of C2+C3) in FIG. 4B.

Series connected capacitors 301 and 401 store the same charge (Q). Because charge (Q) is equal to capacitance times voltage (C×V), the voltage divider circuit of FIG. 4B can be represented by equation (1) below.

Q=C1×(V_{IN}−V1)=(C2+C3)×(V1−0) (1)

Equation (1) can be simplified to create equation (2) below.

V_{IN}=V1×(C1+C2+C3)/C1 (2)

Comparator 305 will switch from a low output voltage to provide a high output voltage when the voltage V1 exceeds the reference voltage V_{REF}. The value of the input voltage V_{IN} under these conditions defines the trip-point (threshold) of comparator 305 for rising edges of the input signal V_{IN}. The trip point for a rising edge of the input signal V_{IN}, which is hereinafter referred to as V_{IN}(+), can therefore be defined as follows.

V_{IN}(+)=V_{REF}×(C1+C2+C3)/C1 (3)

When the voltage V1 applied to the positive input terminal of comparator 305 is greater than the reference voltage V_{REF} applied to the negative input terminal of comparator 305, the output voltage V_{OUT} provided by hysteresis circuit 300 is equal to V_{IN}. (The present embodiment assumes that the voltage swing of the input voltage V_{IN} is equal to the voltage swing of the output voltage V_{OUT}. In the described example, the input voltage V_{IN} and the output voltage V_{OUT} both have a voltage swing between ground and the V_{DD} supply voltage.) Under these conditions, the voltage divider circuit including capacitors 301-303 may be drawn as illustrated in FIG. 5A (wherein the counter-electrode of capacitor 303 is coupled to receive the input voltage V_{IN}). The voltage divider circuit of FIG. 5A may be re-drawn as illustrated in FIG. 5B by combining capacitors 301 and 303 to form equivalent capacitor 501 (which has a capacitance of C1+C3). Because series connected capacitors 501 and 302 store the same charge, the voltage divider circuit of FIG. 5B may be represented by equation (4) below.

(C1+C3)×(V_{IN}−V1)=C2×(V1−0) (4)

Equation (4) can be simplified to create equation (5) below.

V_{IN}=V1×(C1+C2+C3)/(C1+C3) (5)

Comparator 305 will switch from a high output voltage to provide a low output voltage when the voltage V1 becomes less than the reference voltage V_{REF}. The value of the input voltage V_{IN} under these conditions defines the trip-point (threshold) of comparator 305 for falling edges of the input signal V_{IN}. The trip point for a falling edge of the input signal V_{IN}, which is hereinafter referred to as V_{IN}(−), can therefore be defined as follows.

V_{IN}(−)=V_{REF}×(C1+C2+C3)/(C1+C3) (6)

The hysteresis voltage (V_{H}) is the difference between the trip-points of comparator 305 for rising and falling edges of the output signal V_{OUT}. That is, the hysteresis voltage V_{H} is equal to the difference between V_{IN} (+) and V_{IN} (−). Subtracting equation (6) from equation (3) results in the following equations (7-11).

$$\begin{matrix}{V}_{H} = {V}_{IN} ( + ) - {V}_{IN} ( - ) & ( 7 ) \\ {V}_{H} = {V}_{REF} \times ( C 1 + C 2 + C 3 ) / C 1 - {V}_{REF} \times ( C 1 + C 2 + C 3 ) / ( C 1 + C 3 ) & ( 8 ) \\ {V}_{H} = {V}_{REF} \times ( C 1 + C 2 + C 3 ) \times ( C 1 + C 3 ) / [ C 1 \times ( C 1 + C 3 ) ] - {V}_{REF} \times ( C 1 + C 2 + C 3 ) \times C 1 / [ C 1 \times ( C 1 + C 3 ) ] & ( 9 ) \\ {V}_{H} = \frac{{V}_{REF} \times ( C 1 + C 2 + C 3 ) \times [ ( C 1 + C 3 ) - C 1 ]}{[ C 1 \times ( C 1 + C 3 ) ]} & ( 10 ) \\ {V}_{H} = \frac{{V}_{REF} \times ( C 1 + C 2 + C 3 ) \times C 3}{[ C 1 \times ( C 1 + C 3 ) ]} & ( 11 )\end{matrix}$$

In typical applications, the hysteresis voltage V_{H} is much less than the reference voltage V_{REF}. To accomplish this result, the value of C3×(C1+C2+C3)/[C1×(C1+C3)] from equation (11) must be very small. Thus, the term “C3×(C1+C2+C3)” must be much smaller than the term “[C1×(C1+C3)]”. For this relationship to exist, the capacitance C3 must be much less than the capacitance C1. Similarly, capacitance C3 must be much less than capacitance C2. As a result, equation (11) may be simplified as follows.

V_{H}=V_{REF}×(C1+C2)×C3/C1² (12)

Using equation (12) simplifies the design and control of threshold hysteresis voltage V_{H}. That is, the hysteresis voltage V_{H} can be precisely control for a given reference voltage V_{REF} by controlling the capacitances C1, C2 and C3 in view of equation (12).

The configuration of hysteresis circuit 300 assumes that the input voltage signal V_{IN} and the output voltage signal V_{OUT} have the same voltage swing (e.g., these signals vary between the same low voltage of 0 Volts and the same high voltage of V_{DD} Volts). However, if the input voltage signal V_{IN} has a different voltage swing than output voltage signal V_{OUT}, a level shifter may be inserted between output terminal 311 and input terminal 310 to compensate for these different voltage swings.

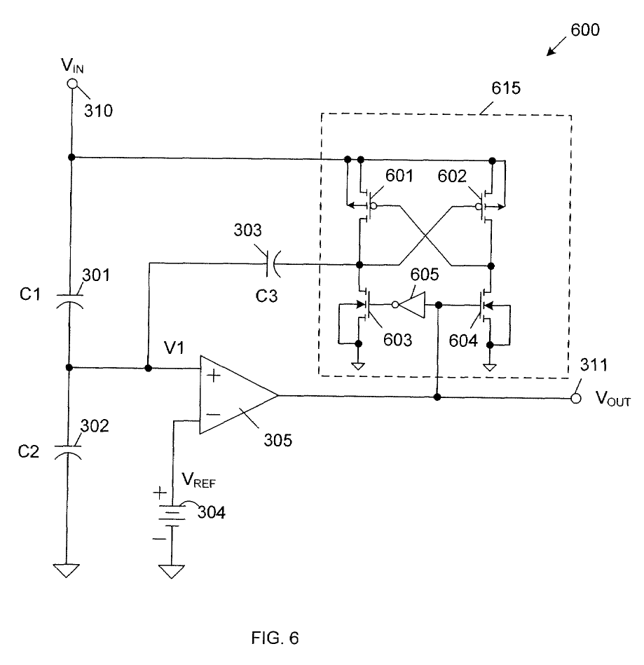

FIG. 6 is a circuit diagram of a comparator 600, which is formed by inserting a level shifter circuit 615 between input terminal 310, output terminal 311 and capacitor 303 of hysteresis circuit 300. The level shifter 615 must be supplied by input voltage signal, V_{IN}, while inverter 605, comparator 305 and voltage reference circuit 304 can all be supplied from the V_{DD} voltage supply. Similar elements in FIGS. 3 and 6 are labeled with similar reference numbers. Thus, comparator 600 includes capacitors 301-303, voltage reference circuit 304, comparator 305, input terminal 310 and output terminal 311, as described above. However, in this embodiment, the output voltage provided by comparator 305 swings between 0 Volts and V_{DD}. Level shifter 615 includes p-channel transistors 601-602, n-channel transistors 603-604 and inverter 605, which are connected in a cross-coupled latch configuration. The input of level shifter 615 is coupled to output terminal 311, and the output of level shifter 615 is coupled to the counter-electrode of capacitor 303. In general, level shifter 615 ensures that the counter-electrode of capacitor 303 has the same voltage swing as the input voltage V_{IN}

Level shifter 615 operates as follows. On a falling transition of the input voltage V_{IN}, the voltage V1 on the positive input terminal of comparator 305 is pulled down to a voltage less than the reference voltage V_{REF}. As a result, the output voltage V_{OUT} is pulled down to ground. In response to the low output voltage V_{OUT}, inverter 605 applies a logic high voltage to the gate of n-channel transistor 603. As a result, n-channel transistor 603 turns on, thereby pulling the counter-electrode of capacitor 303 to ground. This condition is identical to the equations (1)-(3). Note that p-channel transistor 601 is turned off, p-channel transistor 602 is turned on, and n-channel transistor 604 is turned off at this time.

On a rising transition of the input voltage V_{IN}, the voltage V1 on the positive input terminal of comparator 305 is pulled up to a voltage greater than the reference voltage V_{REF}. As a result, the output voltage V_{OUT} is pulled up to the voltage V_{DD}. The high output voltage V_{OUT} is applied to the gate of n-channel transistor 604. As a result, n-channel transistor 604 turns on, thereby pulling the gate of p-channel transistor 601 to ground. In response, p-channel transistor 601 turns on, thereby coupling the counter-electrode of capacitor C3 to the input voltage V_{IN}. This condition is identical to the condition illustrated in FIGS. 5A-5B, and defined by equations (4)-(6). Note that p-channel transistor 602 and n-channel transistor 603 are turned off at this time.

In the above-described manner, level shifter 615 ensures that the counter-electrode of capacitor 303 has the same voltage swing as the input voltage V_{IN}. As a result, hysteresis circuit 600 operates in substantially the same manner described above for hysteresis circuit 300.

In accordance with one embodiment of the present invention, comparators 300 and/or 600 may be used in combination with a reference voltage circuit 304 that generates the reference voltage V_{REF} using a floating gate reference circuit. One example of such a floating gate reference circuit is described in U.S. patent application Ser. No. 11/611,665 (filed on Dec. 15, 2006), which is incorporated by reference. The floating gate reference circuit generates the reference voltage V_{REF} in response to a charge stored on the floating gate of a non-volatile memory transistor. Capacitors 301-303 have a physical structure that is similar to the physical structure of the floating gate non-volatile memory transistor. As a result, capacitors 301-303 and the floating gate non-volatile memory transistor exhibit a similar temperature coefficient. This advantageously allows the temperature coefficient of the capacitive voltage divider circuit (C1+C2+C3) to be compensated by the temperature coefficient of the floating gate reference circuit.

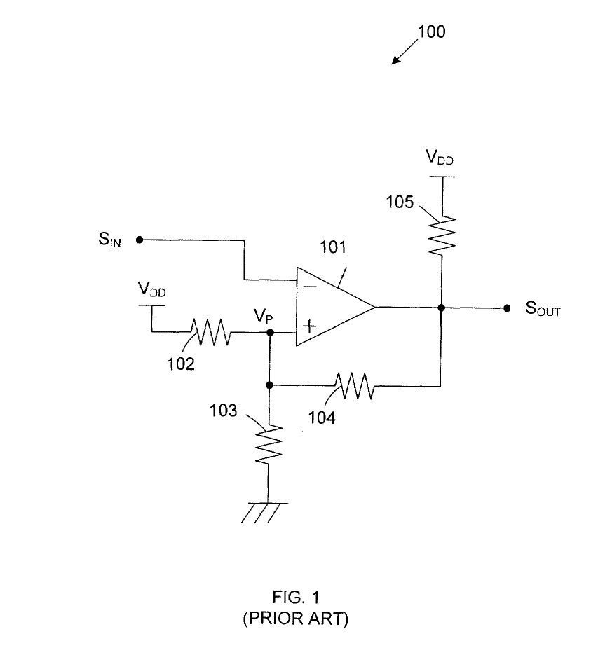

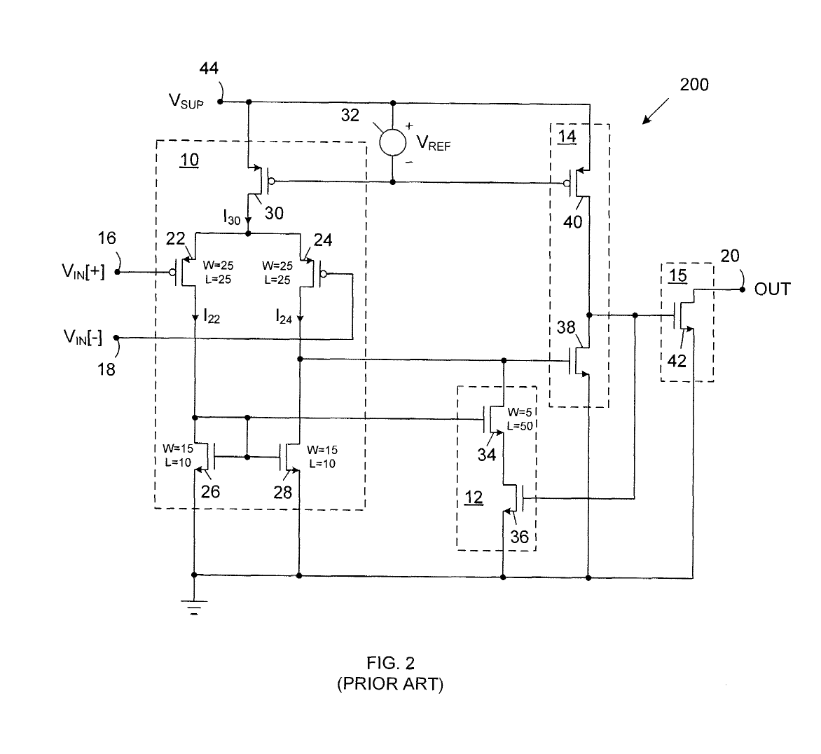

Another advantage of the present invention is that the capacitive divider circuit is faster than a conventional resistive divider circuit. The resistors used in a conventional hysteresis circuit (e.g., the Schmitt trigger circuit of FIG. 1), typically have very large resistance values in order to minimize the quiescent current of the circuit. Resistors having large resistance values require large layout areas and result in high parasitic capacitances. These high parasitic capacitances result in a slow operating speed. Advantageously, the capacitive divider circuit of the present invention inherently exhibits zero quiescent current. Moreover, the layout area required to implement hysteresis circuits 300 and 600 is significantly less than the layout area required to implement a conventional hysteresis circuit using a resistive divider circuit, largely because of the relatively large layout area required by the resistors.

In conclusion, the present invention offers a hysteresis circuit with zero static current, a maximum speed limited only by the speed of the comparator, and a small layout area. Moreover, if the present invention is used in combination with a floating gate reference voltage circuit, the temperature coefficient of the trip point of the comparator will be minimized.

Although the invention has been described in connection with several embodiments, it is understood that this invention is not limited to the embodiments disclosed, but is capable of various modifications, which would be apparent to one of ordinary skill in the art. Accordingly, the present invention is only limited by the following claims.

We claim:

1. A hysteresis circuit comprising:
an input terminal configured to receive an input signal of the hysteresis circuit;
a voltage supply terminal configured to receive a first supply voltage;
a comparator configured to be powered by the input signal of the hysteresis circuit, wherein the comparator has a first input terminal, a second input terminal and an output terminal;
a first capacitor coupled between the input terminal and the first input terminal of the comparator;
a second capacitor coupled between the voltage supply terminal and the first input terminal of the comparator;
a third capacitor coupled between the first input terminal of the comparator and an output terminal of the comparator; and
a reference voltage terminal coupled to receive a reference voltage, wherein the reference voltage terminal is coupled to the second input terminal of the comparator.

2. The hysteresis circuit of claim 1, further comprising a reference voltage circuit coupled to the reference voltage terminal, wherein the reference voltage circuit generates the reference voltage.

3. The hysteresis circuit of claim 2, wherein the reference voltage circuit comprises a floating gate device having a similar construction to the first, second and third capacitors.

4. The hysteresis circuit of claim 1, wherein the first supply voltage is ground.

5. The hysteresis circuit of claim 1, wherein the comparator is further powered by the first supply voltage.

6. The hysteresis circuit of claim 1
a comparator having a first input terminal, a second input terminal and an output terminal;
a capacitive voltage divider circuit comprising a first capacitor, a second capacitor and a third capacitor, each commonly coupled to the first input terminal of the comparator; and
a voltage reference circuit coupled to the second input terminal of the comparator.

7. The hysteresis circuit of claim 6, wherein the first capacitor is further coupled to an input terminal configured to receive an input signal of the hysteresis circuit.

8. The hysteresis circuit of claim 7, wherein the second capacitor is further coupled to a voltage supply terminal configured to receive a supply voltage.

9. The hysteresis circuit of claim 8, wherein the third capacitor is further coupled to the output terminal of the comparator.

10. The hysteresis circuit of claim 9, wherein the output terminal of the comparator has a voltage swing between a voltage of the input signal and the supply voltage.

11. The hysteresis circuit of claim 9, wherein the comparator is powered by the input signal and the supply voltage.

12. The hysteresis circuit of claim 9, wherein the first, second and third capacitors exhibit first, second and third capacitances, respectively, and wherein the third capacitance is smaller than the first capacitance and the second capacitance.

13. A method of implementing a hysteresis circuit, comprising:
applying a reference voltage to a comparator;
applying an input signal to a capacitive voltage divider circuit, thereby generating an input control voltage;
applying the input control voltage to the comparator;
generating an output signal with the comparator in response to the reference voltage and the input control voltage; and
configuring the capacitive voltage divider circuit in response to the output signal of the comparator.

14. The method of claim 13, wherein the step of configuring the capacitive voltage divider circuit comprises applying the output signal of the comparator to a capacitor of the capacitive voltage divider circuit.

15. The method of claim 13, wherein the step of configuring the capacitive voltage divider circuit comprises coupling a third capacitor in parallel with a first capacitor or a third capacitor in response to the output signal of the comparator.

16. The method of claim 15, further comprising:
coupling the third capacitor in parallel with the second capacitor if the input control voltage is less than the reference voltage; and
coupling the third capacitor in parallel with the first capacitor if the input control voltage is greater than the reference voltage.

17. The method of claim 13, wherein the step of applying the input signal to the capacitive voltage divider circuit comprises applying the input signal to a pair of series-connected capacitors, wherein the input control voltage is provided at a common node of the pair of series-connected capacitors.

18. The method of claim 17, further comprising applying the output signal to a capacitor coupled to the common node of the pair of series-connected capacitors.
